(19) United States
(12) Patent Application Publication
(10) Pub. No.: US 2010/0265639 A1
(43) Pub. Date: Oct. 21, 2010

(54) MULTIFUNCTIONAL PORTABLE ELECTRONIC DEVICE

(75) Inventors: YAN-LONG LIU, Shenzhen (CN); HSIAO-HUA TU, Shindian (TW); JUN WANG, Shenzhen (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/697,388

(22) Filed: Feb. 1, 2010

(30) Foreign Application Priority Data
Apr. 16, 2009 (CN) 200910301595.3

(51) Int. Cl. H05K 7/00

(52) U.S. Cl. 361/679.01

(57) ABSTRACT

A multifunctional portable electronic device includes a housing for containing electronic circuitry of a portable electronic device, a cover, and an operating mechanism. The operating mechanism includes an operating member rotatably mounted in the housing, and an elastic member resisting between the operating member and the housing to provide an elastic force to push one end of the operating member out of the housing.

### BACKGROUND

1. Technical Field

The disclosure generally relates to portable electronic devices, particularly to a multifunctional portable electronic device that can also be used as an exercise aid.

2. Description of Related Art

With developments of wireless communication and information processing technologies, portable electronic devices such as mobile phones and personal digital assistants (PDAs) are now in widespread use, and consumers may now enjoy the full convenience of high tech products almost anytime and anywhere. However, people can get tired from operating the portable electronic devices for an extended time, and may wish to exercise their hands.

Therefore, there is room for improvement within the art.

### BRIEF DESCRIPTION OF THE DRAWINGS

Many aspects of the multifunctional portable electronic device can be better understood with reference to the following drawings. The components in the drawings are not necessarily drawn to scale, the emphasis instead being placed upon clearly illustrating the principles of the multifunctional portable electronic device.

FIG. 1 shows a disassembled, schematic view of a multifunctional portable electronic device, according to an exemplary embodiment.

FIG. 2 shows a schematic view of the multifunctional portable electrical device shown in FIG. 1 with a cover detached.

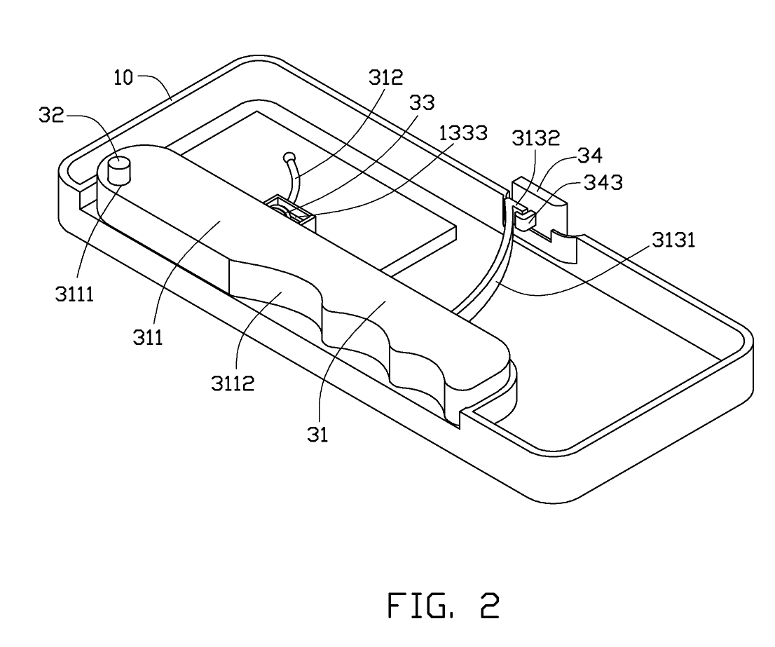

FIG. 3 is similar to FIG. 2, but showing the multifunctional portable electrical device in another state.

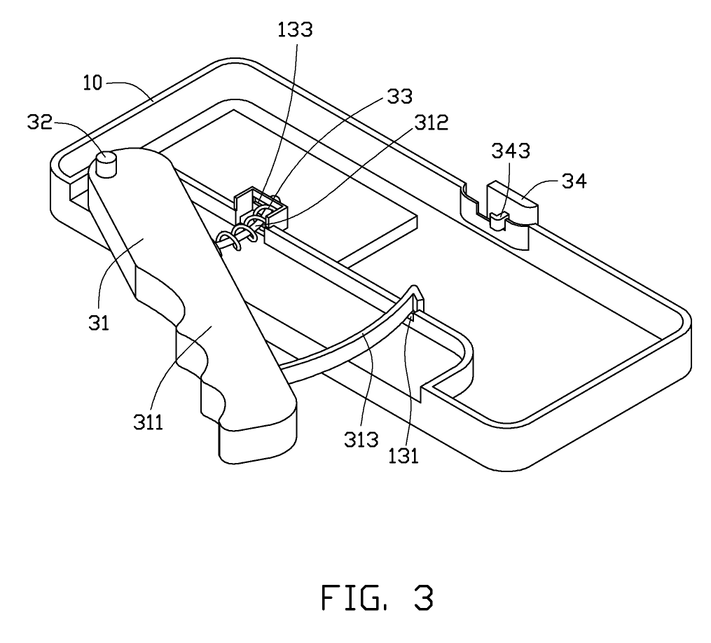

### DETAILED DESCRIPTION

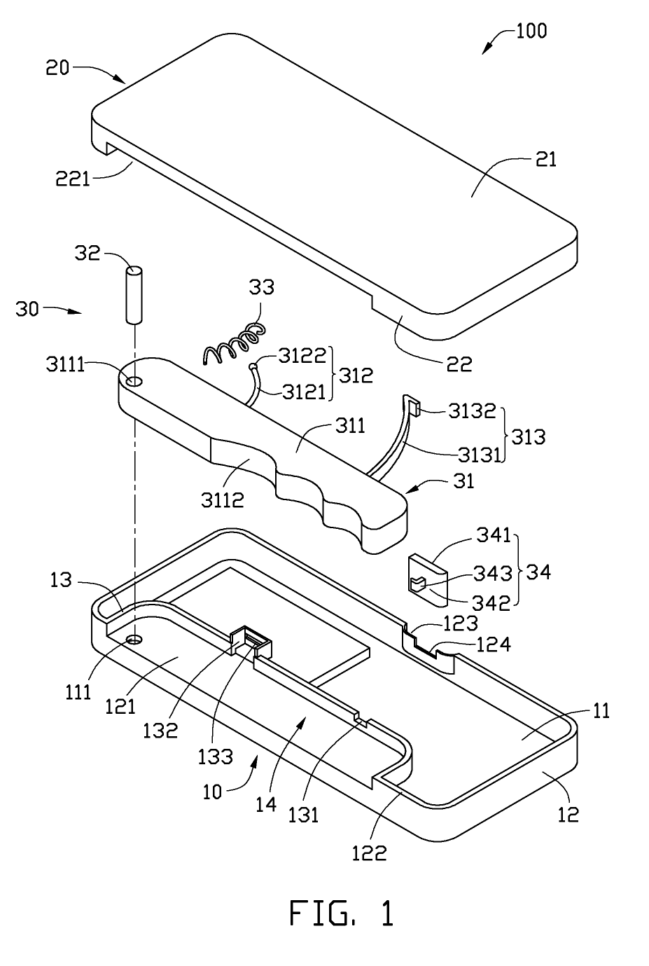

Referring to FIG. 1, an exemplary embodiment of a multifunctional portable electronic device 100, such as a mobile phone or a personal digital assistant (PDA) includes a housing 10, a cover 20, and an operating mechanism 30. The cover 20 is assembled to the housing 10. The operating mechanism 30 is mounted between the housing 10 and the cover 20.

The housing 10 is a shell of the portable electronic device 100 and contains electrical circuitry (now shown) for the portable electronic device. Housing 10 includes a bottom wall 11 and a peripheral wall 12. The bottom wall 11 is substantially planar. A hole 111 is defined in the bottom wall 11 adjacent to one end. The peripheral wall 12 perpendicularly extends from perimeter edges of the bottom wall 11. A first opening 121 is defined in one side of the peripheral wall 12, which forms two ends 122. The peripheral wall 12 has a receiving portion 123 opposite to the first opening 121, and defining a notch 124. A substantially U-shaped extending wall 13 protrudes from the bottom wall 11 The extending wall 13 forms a receiving space 14 with the bottom wall 11 to mount the operating mechanism 30. A guiding groove 131 is defined in the extending wall 13 opposite to the notch 124. A substantially U-shaped receiving frame 132 is formed in the extending wall 13 defining a slot 133 aligned with the guiding groove 131.

The cover 20 includes an upper wall 21 and a sidewall 22 extending from perimeter edges of the upper wall 21. A second opening 221 is defined in the sidewall 22 corresponding to the first opening 121. The cover 20 is generally the same size as the housing 10 and can be assembled to the housing using, for example, latches (not shown).

The operating mechanism 30 includes an operating member 31, a pivoting element 32, an elastic member 33, and a button 34. The operating member 31 includes an operating portion 311, a positioning portion 312, and a latching portion 313. The operating portion 311 can be received in the receiving space 14. A positioning hole 3111 is defined in and adjacent to one end of the operating portion 311, corresponding to the hole 111 of the housing 10. A undulating and rippled grip-like surface 3112 is formed on one side of the operating portion 331. The positioning portion 312 includes an arcuate rod 3121 and a stopper 3122 formed on one distal end of the rod 3121. The rod 3131 is configured to slide within the slot 133. The stopper 3122 is made of elastic materials such as rubber or sponge and can pass through the slot 133 and stop the rod 3131 from disengaging from the slot 133 of the housing 10. The latching portion 313 includes an arcuate shaft 3131 and a hook 3132 formed at one end thereof. The shaft 3131 is configured to slide within the guiding groove 131. The hook 3132 is engaged with the guiding groove 131 to stop the shaft 3131 from disengaging from the extending wall 13 of the housing 10. The positioning portion 312 and the latching portion 313 are secured to one side of the operating portion 331 opposite to the grip surface 3112.

The pivoting element 32 is engaged in the hole 111 and the positioning hole 3111 to rotatably assemble the operating member 31 to the housing 10. The elastic member 33 is a helical spring, and can be placed around the rod 3121, and resists between the receiving frame 132 of the housing 10 and the operating member 31.

The button 34 includes an operating surface 341 and a mounting surface 342 opposite to the operating surface 341. A clasp 343 is formed on the mounting surface 342. The clasp 343 is configured to interlock with the hook 3132 to keep the operating portion 31 completely received in the receiving space 14.

In assembly, the elastic member 33 is placed around the rod 3121, and is compressed, the stopper 3122 is passed through the slot 133. Also the rod 3121 is slidably disposed in the slot 133. The shaft 3131 of the latching portion 313 is disposed in the guiding groove 131 of the housing 10 and the operating portion 31 is partially received in the receiving space 14. Then, the pivoting element 32 is engaged in the positioning hole 3111 and the hole 111 to rotatably assemble the operating portion 311 to the housing 10. After that, the button 34 is slidably mounted in the receiving portion 123 with the clasp 343 interlocking with the hook 3132. Thus, the operating portion 311 is completely received in the receiving space 14. Finally, the cover 20 is assembled to the housing 10.

To use the multifunctional portable electronic device 100 as an exercise aid, the button 34 is moved to release the clasp 343 from the hook 3132. Thus, the operating member 311 rotates relative to the pivoting element 32, and one end is pushed out of the receiving space 14 from the first opening 121 by the elastic force provided by the elastic member 33. The user can operate the operating portion 311 to be completely received in the receiving space 14 by resisting the elastic force of the elastic member 33 repeatedly, thus exercising their hands.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A multifunctional portable electronic device, comprising:
a housing for containing electronic circuitry of the portable electronic device;
a cover mounted to the housing; and
an operating mechanism; comprising:
an operating member rotatably assembled in the housing, and
an elastic member resisting between the operating member and the housing to provide an elastic force to push one end of the operating member out of the housing.

2. The multifunctional portable electronic device as claimed in claim 1, wherein the operating mechanism further includes a button, the button may engage the operating member to retain the operating member completely within the housing.

3. The multifunctional portable electronic device as claimed in claim 1, wherein the operating mechanism further includes a pivoting element, the pivoting element is receivable in a hole defined in the housing and a positioning hole defined in the operating member to rotatably assemble the operating member to the housing.

4. The multifunctional portable electronic device as claimed in claim 1, wherein the operating member includes an operating portion, a positioning portion and a latching portion, the positioning portion and the latching portion secure on one side of the operating portion, the elastic member is placed around the positioning portion, the latching portion interlocks with the button.

5. The multifunctional portable electronic device as claimed in claim 4, wherein one side of the operating portion forms a grip surface thereon, opposite to the positioning portion and the latching portion.

6. The multifunctional portable electronic device as claimed in claim 4, wherein the positioning portion includes rod and a stopper formed on one distal end of the rod, the elastic member placed around the rod.

7. The portable electronic device as claimed in claim 6, wherein the housing includes the latching portion having a shaft and a hook formed at one end thereof.

8. The portable electronic device as claimed in claim 7, wherein the housing includes a bottom wall and a peripheral wall extending from perimeter edges of the bottom wall; the peripheral wall defines a first opening therein and forms two ends; a receiving portion is formed in the peripheral wall opposite to the first opening with a notch defined therein to mount the bottom; a extending wall protrudes from the bottom wall, and forms a receiving space with the bottom wall to mount the operating mechanism.

9. The portable electronic device as claimed in claim 8, wherein the extending wall defines a guiding groove therein opposite to the notch, the shaft is disposed in the guiding groove.

10. The portable electronic device as claimed in claim 8, wherein a substantially U-shaped receiving frame is formed in the extending wall with a slot defined therein, the stopper passes through the slot, the rod is slidably disposed in the slot.

11. A multifunctional portable electronic device, comprising:
a housing for containing electronic circuitry of a portable electronic device;
a cover mounted to the housing; and
an operating mechanism mounted between the housing and the cover; the operating mechanism comprising:
an operating member rotatably mounted to the housing, and
an elastic member mounted between the operating member and the housing, wherein when the operating member is released from the housing, the elastic member provides an elastic force to push one end of the operating member out of the housing.

12. The multifunctional portable electronic device as claimed in claim 10, wherein the operating mechanism further includes a button, the button may engage the operating member to retain the operating member completely within the housing.

13. The multifunctional portable electronic device as claimed in claim 10, wherein the operating mechanism further includes a pivoting element, the pivoting element is receivable in a pivoting element hole defined in the housing and a positioning hole defined in the operating member to rotatably assemble the operating member to the housing.

14. The multifunctional portable electronic device as claimed in claim 11, wherein the operating member includes an operating portion, a positioning portion and a latching portion, the positioning portion and the latching portion secure on one side of the operating portion, the elastic member is placed around the positioning portion, the latching portion interlocks with the button.

15. The multifunctional portable electronic device as claimed in claim 14, wherein one side of the operating portion forms an undulated surface thereon, opposite to the positioning portion and the latching portion.

16. The multifunctional portable electronic device as claimed in claim 14, wherein the positioning portion includes rod and a stopper formed on one distal end of the rod, the elastic member placed around the rod.

17. The portable electronic device as claimed in claim 16, wherein the latching portion includes a shaft and a hook formed at one end thereof.

18. The portable electronic device as claimed in claim 17, wherein the housing includes a bottom wall and a peripheral wall extending from perimeter edges of the bottom wall;
the peripheral wall defines a first opening and forms two ends; a receiving portion is formed in the peripheral wall opposite to the first opening with a notch defined therein to mount the bottom; a extending wall protrudes from the bottom wall, and forms a receiving space with the bottom wall to mount the operating mechanism.

19. The portable electronic device as claimed in claim 18, wherein the extending wall defines a guiding groove therein opposite to the notch, the shaft is disposed in the guiding groove.

20. The portable electronic device as claimed in claim 18, wherein a substantially U-shaped receiving frame is formed in the extending wall with a slot defined therein, the stopper passes through the slot, the rod slidably disposed in the slot.
